(19) United States
(12) Patent Application Publication
(10) Pub. No.: US 2008/0164522 A1
(43) Pub. Date: Jul. 10, 2008

(54) Semiconductor device and manufacturing method thereof

(75) Inventor: Noriaki Mikasa, Tokyo (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Elpida Memory, Inc., Tokyo (JP)

(21) Appl. No.: 12/007,111

(22) Filed: Jan. 7, 2008

(30) Foreign Application Priority Data
Jan. 9, 2007 (JP) 2007-001335

(51) Int. Cl. H01L 21/336; H01L 29/78

(52) U.S. Cl. 257/345; 438/282; 257/E21.409; 257/E29.27

(57) ABSTRACT

To provide a semiconductor device that has a three dimensional gate dielectric film, is easily manufactured, and a gate structure thereof can be easily miniaturize. A semiconductor device comprises: a three-dimensional gate dielectric film formed on a semiconductor substrate; a gate electrode that contacts the gate dielectric film and protrudes from the semiconductor substrate; a source electrode and a drain electrode that are formed in a diffusion layer region of the semiconductor substrate around the gate dielectric film; a protective dielectric film that covers a top face of the semiconductor substrate around the gate electrode and a side face of the gate electrode protruding from the semiconductor substrate; and an inter-layer dielectric film that is laminated over the protective dielectric film.

### BACKGROUND OF THE INVENTION

1. Field of the Invention

The present invention relates to a semiconductor device that can be easily processed even with a minute gate length and is compatible with transistor miniaturization, and a manufacturing method thereof.

Priority is claimed on Japanese Patent Application No. 2007-001335, filed Jan. 9, 2007, the content of which is incorporated herein by reference.

2. Description of Related Art

A memory cell such as a Dynamic Random Access Memory (DRAM) includes a capacitor and a transistor for selection. When a semiconductor element is miniaturized, the size of the transistor is also reduced, and this size reduction makes a short channel effect of the transistor noticeable. In a large-capacity DRAM, since a reduction in the channel length of the transistor accompanies the reduction in the size of the memory cell, the performance of the transistor deteriorates, leading to a problematic decline in the retention and writing characteristics of the DRAM memory cell.

Examples of countermeasures that have been developed against this short channel effect of a transistor include a recessed transistor having a three-dimensional channel structure wherein trenches are formed in a semiconductor substrate, or a Fin-field effect transistor (Fin-FET) having a three-dimensional channel structure in which a silicon fin is provided on the substrate. In a recessed transistor, a trench is provided in the semiconductor substrate and a gate electrode is formed in this bench with a gate dielectric film therebetween, enabling the three-dimensional trench interface to be effectively used as a channel and thereby increasing the channel length. In a Fin-FET, a silicon fin is provided on the semiconductor substrate, and a gate electrode is arranged such as to straddle this fin, thereby obtaining a three-dimensional channel structure.

FIGS. 11 and 12 illustrate an example of this type of recessed transistor structure. In the transistor of this example, a silicon diffusion layer 100 and an inter-diffusion layer separating dielectric film 101 (e.g. silicon oxide film) that partitions the silicon diffusion layer 100 by enclosing it, are disposed on a semiconductor substrate (not shown); a gate 103, a source contact 104, and a drain contact 105 are also provided.

In the transistor with this structure, in a case where the gate 103 is constituted by a polysilicon part 201, a metal film 202 (e.g. tungsten film), a protective dielectric film (side wall dielectric film) 203 (e.g. silicon nitride film) for preventing metal contamination caused by scattering to the silicon diffusion layer 100, and a hard mask dielectric film 204 (e.g. silicon nitride film) for processing the polysilicon part 201 and the metal film 202, FIG. 12 is a cross-sectional view along the line A1-A2 of FIG. 11, and FIG. 13 is a cross-sectional view along the line B1-B2 of FIG. 11. FIG. 14 is a cross-sectional view along the line A1-A2 when using a Fin-FET transistor structure having a three dimensional channel structure similar to that of FIG. 11, and FIG. 15 is a cross-sectional view along the line B1-B2.

As an example of a conventional recessed transistor, there is a technique of forming a recessed channel trench by etching of a silicon substrate and a separating dielectric film using a mask layer pattern that has large etch selectivity to the silicon substrate. (See Japanese Unexamined Patent Application, First Publication No. 2005-183976 {hereinafter “Patent Literature 1”}).

In Patent Literature 1, after forming a gate dielectric film and a recessed gate stack in the recessed channel trench, the recessed channel array transistor is completed by forming a source and a drain in the silicon substrate on both side walls of the recessed gate stack.

In Patent Literature 1, when the recessed channel trench is formed, its depth is easily adjusted using a mask layer pattern that has large etch selectivity to the silicon substrate, increasing the etching evenness of the silicon substrate. Moreover, Patent Literature 1 mentions a silicon nitride film and a silicon oxide film as examples of a mask layer that is provided over a buffer dielectric film. Using this nitride film or oxide film as the mask layer, dry etching or wet etching is performed to form a recessed channel trench; a gate dielectric film and a recessed gate stack including a polysilicon layer, a gate metal layer and a capping layer are then formed in the recessed channel trench.

In another technique, a gate dielectric film, a polysilicon film, a high melting point metal film, and a gate cap dielectric film are sequentially laminated on the semiconductor substrate; the gate cap dielectric film and the high melting point metal film are selectively removed by etching; a double-layer protective film comprising a silicon nitride films and a silicon oxide film is provided over side faces of the gate cap dielectric film, the high melting point metal film, and the polysilicon film; the polysilicon film etched using this double-layer protective film as a mask; and a light oxidation process is then performed to form a silicon oxide film on side faces of the polysilicon film. (See Japanese Unexamined Patent Application, First Publication No. 2006-114755 {hereinafter “Patent Literature 2”}).

In this type of transistor structure, with the aim of miniaturizing the elements, the gate 103 must be further miniaturized by processing. However, since the protective dielectric layer 203 for preventing metal contamination is liable to become ineffective if it is made any narrower (thinner), the narrowness of the metal film 202 in a recessed transistor must be increased from the state shown in FIG. 12 to that shown in FIG. 16. In the case of a Fin-FET transistor, the structure of the metal film 202 shown in FIG. 14 must be made narrower as shown in the structure of FIG. 17.

The conventional types of gate structure described above have problems such as the following.

(1) Gate resistance increases as the metal film 202 is further miniaturized, leading to a problem of deterioration in the element characteristics.

(2) As the metal film 202 is further miniaturized, patterns of the hard mask dielectric film 204 which functions as a processing mask and a photo resist (PR) mask for dielectric film processing must be miniaturized, making processing difficult.

### SUMMARY OF THE INVENTION

The present invention has been realized after consideration of the above points, and aims to provide a semiconductor device that can be easily miniaturized even with a minute gate length and can suppress increase in gate resistance, and a manufacturing method thereof.

A first aspect of a semiconductor device in accordance with the present invention comprises: a three-dimensional gate dielectric film formed on a semiconductor substrate; a gate electrode that contacts the gate dielectric film and protrudes from the semiconductor substrate; a source electrode and a drain electrode that are formed in a diffusion layer region of the semiconductor substrate around the gate dielectric film; a protective dielectric film that covers a top face of the semiconductor substrate around the gate electrode and a side face of the gate electrode protruding from the semiconductor substrate; and an inter-layer dielectric film that is laminated over the protective dielectric film.

A second aspect of a semiconductor device in accordance with the present invention comprises: a recessed channel transistor including a trench formed in a semiconductor substrate; a gate electrode formed in the trench with a gate dielectric film therebetween, at least a part of the gate electrode extending above the semiconductor substrate; a diffusion layer region arranged in the semiconductor substrate near the gate electrode with the gate dielectric film therebetween; and a source electrode and a drain electrode that contact the diffusion layer region; a gate electrode extension part that is made of a conductive material and is laminated on the gate electrode so as to extend the gate electrode; a protective dielectric film that covers the semiconductor substrate around the gate electrode and surrounds a side face of the gate electrode that protrude from the trench; and an inter-layer dielectric film formed over the protective dielectric film.

A third aspect of a semiconductor device in accordance with the present invention comprises: a transistor including a protective dielectric film formed on a semiconductor substrate; a trench formed in the protective dielectric film so as to reach the semiconductor substrate; a gate electrode formed in the trench with a gate dielectric film therebetween; a diffusion layer region arranged in the semiconductor substrate near the gate electrode with the gate dielectric film therebetween; and a source electrode and a drain electrode that contact the diffusion layer region; a gate electrode extension part made of a conductive material and laminated on the gate electrode so as to extend the gate electrode; a protective dielectric film that covers the semiconductor substrate around the gate electrode and surrounds a side face of the gate electrode; and an inter-layer dielectric film formed over the protective dielectric film.

Preferably, in the first to third aspects of the semiconductor device, a top face of the protective dielectric film, a top face of the gate dielectric film, and a top face of the gate electrode are polished by chemical mechanical polishing so as to be aligned in a single plane.

Preferably, the first aspect of the semiconductor device further comprises a gate electrode extension part whose side face is exposed and that is formed on the gate electrode, and the gate electrode is surrounded by the protective dielectric film, and the gate electrode extension part is positioned above the protective dielectric film.

Preferably, in the second and third aspects of the semiconductor device, the gate electrode is surrounded by the protective dielectric film, and the gate electrode extension part is positioned above the protective dielectric film.

Preferably, in the first to third aspects of the semiconductor device, the diffusion layer region becomes a source region and a drain region, the source electrode passes through the protective dielectric layer and contacts the source region, and the drain electrode passes through the protective dielectric film and contacts the drain region.

Preferably, the first aspect of the semiconductor device further comprises a gate electrode extension part that is laminated on the gate electrode, and the thickness of the gate electrode extension part is equal to or greater than the width of a trench in which the gate electrode and the gate dielectric film are formed.

Preferably, in the second and third aspects of the semiconductor device, the thickness of the gate electrode extension part is equal to or greater than the width of the trench in which the gate electrode and the gate dielectric film are formed.

Preferably, the first aspect of the semiconductor device further comprises a conductive part that is laminated on the gate electrode, and the width of the conductive part is equal to or greater than the width of a trench in which the gate dielectric film and the gate electrode are formed, and a side face of the conductive part is exposed.

Preferably, in the second and third aspects of the semiconductor device, the gate electrode extension part is a conductive part having a width that is equal to or greater than the width of the trench in which the gate dielectric film and the gate electrode are formed, and a side face of the conductive part is exposed.

A first aspect of a method of manufacturing a semiconductor device in accordance with the present invention comprises: forming an element separating dielectric film in a semiconductor substrate where a diffusion layer region is formed; forming a protective dielectric film on the semiconductor substrate where the element separating dielectric film is formed; patterning the protective dielectric film, and forming a trench by etching the protective dielectric film and the semiconductor substrate while using the patterned protective dielectric film as a mask; forming a gate dielectric film along an inner face of the trench by performing an oxidation process to the diffusion layer region; forming a gate electrode on an inner side of the gate dielectric film by forming a polysilicon layer on the semiconductor substrate; flattening a surface of the semiconductor substrate by chemical mechanical polishing using the protective dielectric film as a stopper to align a top face of the protective dielectric film, a top face of the gate dielectric film, and a top face of the gate electrode in a single plane; forming a gate electrode extension part comprising a conductive material on the gate electrode; and forming a source electrode and a drain electrode that pass through the protective dielectric film and contact the diffusion layer region on a side of the gated electric film.

A second aspect of a method of manufacturing a semiconductor device in accordance with the present invention comprises: forming an element separating dielectric film in a semiconductor substrate where a diffusion layer region is formed; forming a protective dielectric film on the semiconductor substrate where the element separating dielectric film is formed; patterning the protective dielectric film and forming a trench that reaches a surface of the semiconductor substrate; forming, inside the trench, a gate dielectric film that reaches the semiconductor substrate and covers an inner face of the trench; forming a gate electrode on an inner side of the gate dielectric film by forming a polysilicon layer on the semiconductor substrate; flattening the surface of the semiconductor substrate by chemical mechanical polishing using the protective dielectric film as a stopper to align a top face of the protective dielectric film, a top face of the gate dielectric film, and a top face of the gate electrode in a single plane; forming a gate electrode extension part comprising a conductive material on the gate electrode; and forming a source electrode and a drain electrode that pass through the protective dielectric film and contact the diffusion layer region on a side of the gate dielectric film.

Preferably, in the first and second aspects of the method of manufacturing a semiconductor device, when the gate electrode extension part is formed on the gate electrode, the gate electrode extension part is formed on the gate electrode in a state where the protective dielectric film covers a top face of the semiconductor substrate and prevents scattering of the conductive material.

Preferably, in the first and second aspects of the method of manufacturing a semiconductor device, the gate electrode extension part is formed on the gate electrode such that a side part of the gate electrode extension part is exposed, and the width of the gate electrode extension part is equal to or exceeds the width of the gate electrode.

As described above, in the present invention, since the semiconductor substrate surrounding the gate electrode is covered by the protective dielectric film and also by the inter-layer dielectric film, when forming the gate electrode extension part on the gate electrode, the formation material does not scatter into the regions of the diffusion layers of the semiconductor substrate surrounding the gate electrode. This eliminates the need for a side protective dielectric layer that was required in the conventional art when forming the gate electrode extension part above the gate electrode. The gate electrode extension part can therefore be made thicker than in the conventional art, miniaturization of the gate structure can be facilitated, and increase in the gate resistance of the gate electrode portion including the gate electrode extension part can be suppressed, thereby suppressing deterioration in the element characteristics.

Even if the gate structure is miniaturized, it is possible to suppress miniaturization of the mask dielectric film used as a processing mask, and to suppress miniaturization of the pattern of a photo resist mask for processing the gate electrode extension part, thereby preventing processing from becoming difficult.

### BRIEF DESCRIPTION OF THE DRAWINGS

FIG. 1 is a diagram of a planar structure of a semiconductor device according to a first embodiment of the present invention.

FIGS. 2A to 2C are diagrams of a partial cross-sectional structure of the semiconductor device shown in FIG. 1, FIG. 2A being a partial cross-sectional view along line X1-X2 of FIG. 1, FIG. 2B being a partial cross-sectional view along line Y1-Y2 of FIG. 1, and FIG. 2C being a partial cross-sectional view along line Y3-Y4.

FIGS. 3A to 3C are explanatory diagrams of a method of manufacturing a semiconductor device in the first embodiment shown in FIG. 1 and FIGS. 2A to 2C, FIG. 3A being a partial cross-sectional view along line X1-X2 in a state where a trench is formed through a protective dielectric film and a pad silicon oxide film in a semiconductor substrate, FIG. 3B being a partial cross-sectional view along line Y1-Y2 in the same state, and FIG. 3C being a partial cross-sectional view along line Y3-Y4 in the same state.

FIGS. 4A to 4C are explanatory diagrams of a method of manufacturing the semiconductor device in the first embodiment shown in FIG. 1 and FIGS. 2A to 2C, FIG. 4A being a partial cross-sectional view along line X1-X2 in a state where a gate electrode is formed in a trench, FIG. 4 B being a partial cross-sectional view along line Y1-Y2 in the same state, and FIG. 4C being a partial cross-sectional view along line Y3-Y4 in the same state.

FIGS. 5A to 5C are explanatory diagrams of a method of manufacturing the semiconductor device in the first embodiment shown in FIG. 1 and FIGS. 2A to 2C, FIG. 5A being a partial cross-sectional view along line X1-X2 in a state where a gate electrode extension part and a mask dielectric film are deposited over a gate electrode, FIG. 5B being a partial cross-sectional view along line Y1-Y2 in the same state, and FIG. 5C being a partial cross-sectional view along line Y3-Y4 in the same state.

FIGS. 6A to 6C are partial cross-sectional structures of a semiconductor device according to a second embodiment of the present invention, FIG. 6A being a partial cross-sectional view along line X1-X2, FIG. 6B being a partial cross-sectional view along line Y1-Y2, and FIG. 6C being a partial cross-sectional view along line Y3-Y4.

FIGS. 7A to 7C are explanatory diagrams of a method of manufacturing the semiconductor device according to the second embodiment shown in FIGS. 6A to 6C, FIG. 7A being a partial cross-sectional view along line X1-X2 in a state where a trench is formed in a protective dielectric film, FIG. 7B being a partial cross-sectional view along line Y1-Y2 in the same state, and FIG. 7C being a partial cross-sectional view along line. Y3-Y4 in the same state.

FIGS. 8A to 8C are explanatory diagrams of a method of manufacturing, the semiconductor device according to the second embodiment shown in FIGS. 6A to 6C, FIG. 8A being a partial cross-sectional view along line X1-X2 in a state where a trench is formed by etching of an element separating dielectric film, FIG. 8B being a partial cross-sectional view along line Y1-Y2 in the same state, and FIG. 8C being a partial cross-sectional view along line Y3-Y4 in the same state.

FIGS. 9A to 9C are explanatory diagrams of a method of manufacturing the semiconductor device according to the second embodiment shown in FIGS. 6A to 6C, FIG. 9A being a partial cross-sectional view along line X1-X2 in a state where a gate electrode is formed in a trench, FIG. 9B being a partial cross-sectional view along line Y1-Y2 in the same state, and FIG. 9C being a partial cross-sectional view along line Y3-Y4 in the same state.

FIGS. 10A to 10C are explanatory diagrams of a method of manufacturing the semiconductor device according to the second embodiment shown in FIGS. 6A to 6C, FIG. 10A being a partial cross-sectional view along line X1-X2 in a state where a gate electrode extension part and a mask dielectric film are deposited over a gate electrode, FIG. 10B being a partial cross-sectional view along line Y1-Y2 in the same state, and FIG. 10C being a partial cross-sectional view along line Y3-Y4 in the same state.

FIG. 11 is a diagram of one example of a planar structure of a conventional recessed semiconductor device.

FIG. 12 is a diagram of the cross-sectional structure taken along the direction of line A1-A2 of FIG. 11.

FIG. 13 is a diagram of the cross-sectional structure taken along the direction of line. B1-B2 of FIG. 11.

FIG. 14 is a diagram of the cross-sectional structure of an example of a conventional Fin-FET taken along line A1-A2.

FIG. 15 is a diagram of the cross-sectional structure of an example of a conventional Fin-FET taken along line B1-B2.

FIG. 16 is a diagram of one example of a cross-sectional structure when the gate structure of a conventional recessed semiconductor device is made small.

FIG. 17 is diagram of one example of a cross-sectional structure when the gate structure of a conventional Fin-FET is made small.

### DETAILED DESCRIPTION OF INVENTION

A semiconductor device according to embodiments of the present invention will be explained with reference to the accompanying drawings. The present invention is not, of course, limited to the embodiments described below.

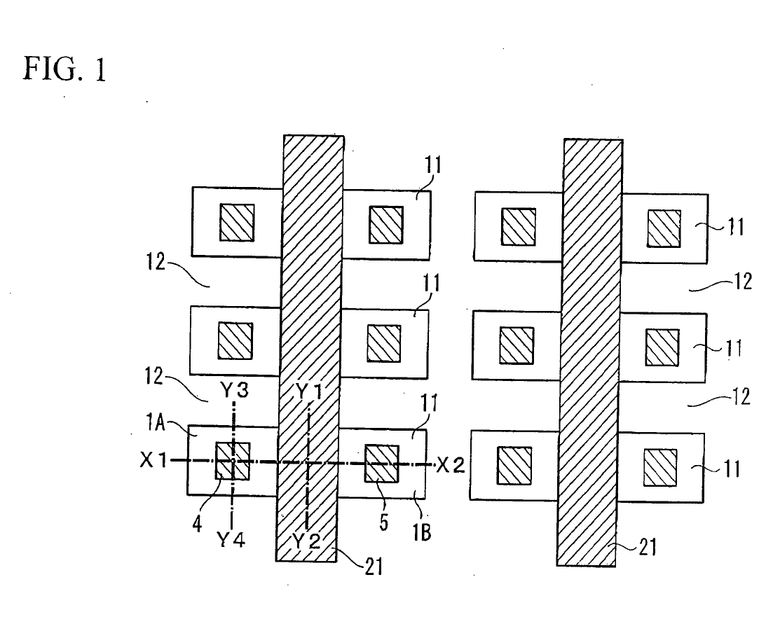

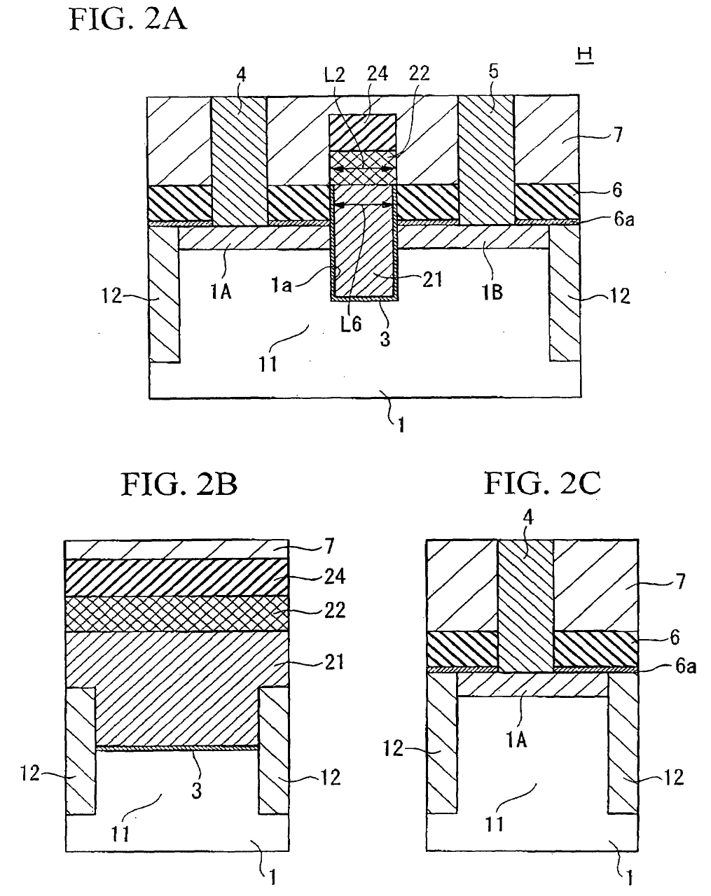

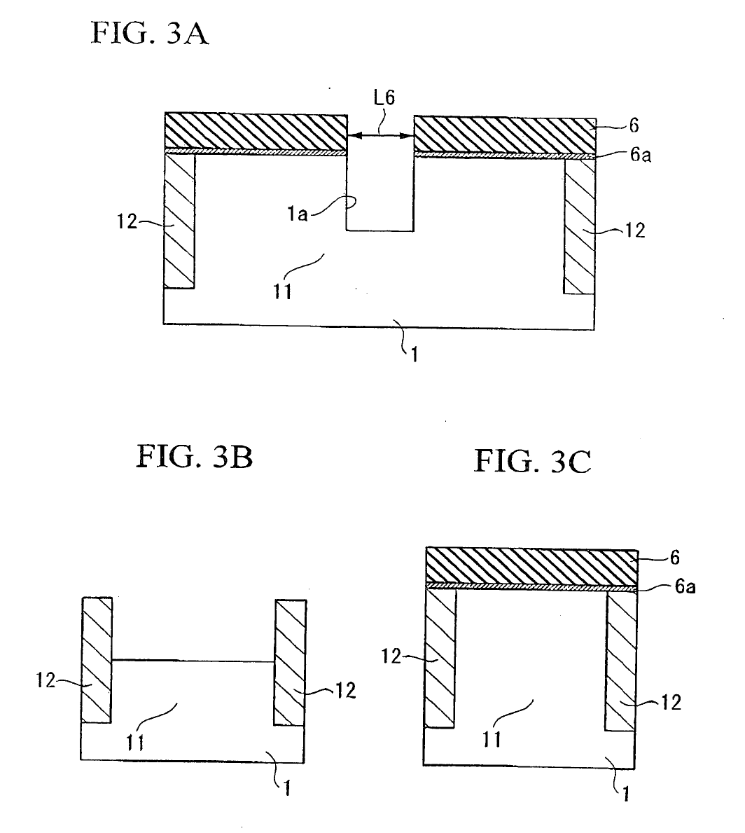

FIG. 1 is a conceptual diagram of a planar structure of a semiconductor device according to embodiments of the present invention. FIGS. 2A to 2C are conceptual diagrams of a cross-sectional stature of a recessed semiconductor device according to a first embodiment of the present invention. FIG. 2A is a cross-sectional view along X1-X2 in the plan view of FIG. 1, FIG. 2B is a cross-sectional view along Y1-Y2 of FIG. 1, and FIG. 2C is a cross-sectional view along Y3-Y4 of FIG. 1. In the explanation below, FIGS. 3A, 4A, 5A, 6A, 7A, 8A, 9A, and 10A are partial cross-sectional views along the same direction as FIG. 2A. Similarly, FIGS. 3B, 4B, 5B, 6, 7B, 8B, 9B, and 10B are partial cross-sectional views along the same direction as FIG. 2B, and FIGS. 3C, 4C, 5C, 6C, 7C, 8C, 9C, and 10C are partial cross-sectional views along the same direction as FIG. 2C.

In these diagrams, a semiconductor substrate 1 applied in a semiconductor device H of this embodiment is formed from a semiconductor conjoining impurities having a predetermined density, e.g. silicon.

As shown in the plan view of FIG. 1, a plurality of active regions 11 where a metal oxide semiconductor (MOS) transistor is formed on a surface of a semiconductor substrate are partitioned by element separating dielectric films 12, whereby adjacent active regions 11 are separated and insulated from each other. A gate electrode 21 that becomes a DRAM word line is provided such as to vertically intersect the center of the active regions 11 along the direction Y1-Y2 of FIG. 1. A diffusion layer 1A that becomes a source is arranged on one side of the gate electrode 21, and a diffusion layer 1B that becomes a drain is arranged on the opposite side. Contact plugs 4 and 5 are provided over the diffusion layers 1A and 1B.

The cross-section Y3-Y4 of FIG. 1 is a vertical cross-section of the diffusion layer 1A where the contact plug 4 is formed. The cross-section X1-X2 of FIG. 1 is a horizontal cross-section of an active region 11. The explanation of this embodiment will describe only the semiconductor device H comprising a MOS transistor formed in one active region 11.

As shown in the cross-sectional views of FIGS. 2A to 2C, in the semiconductor device H of this embodiment, a protective dielectric film 6 is formed on a surface of a semiconductor substrate 1. A trench 1a is provided such that it passes through the protective dielectric film 6 and has a predetermined depth from the surface portion of the semiconductor substrate 1 below it. A gate dielectric film 3 is provided over the inner faces of the trench 1a. A polysilicon gate electrode 21 is formed on the inner side of the gate dielectric film 3. Since the trench 1a passes through the protective dielectric film 6 to a predetermined depth in the semiconductor substrate 1 that forms the active region 11, the top side of the gate dielectric film 3 contacts the protective dielectric film 6, and its bottom side contacts the semiconductor substrate 1.

A gate electrode extension part 22 is made from a conductive metal such as tungsten, and is formed over the gate electrode 21. The width L2 of the gate electrode extension part 22 is equal to the width L6 of the trench 1a (i.e. the total width that includes the width of the gate electrode 21 and the thickness of the gate dielectric film 3 on both sides of the gate electrode 21). A mask dielectric film 24 is formed over the gate electrode extension part 22. An inter-layer dielectric film 7 is provided over all the entire face such as to cover the mask dielectric film 24. Incidentally, while the polysilicon gate electrode 21 and the metal gate electrode extension part 22 are sometimes referred to collectively as “gate electrodes”, in this embodiment they will be treated separately for sake of convenience.

The diffusion layers 1A and 1B which constitute the source and the drain are provided on the left and right sides of the trench 1a, the contact plugs 4 and 5 being formed such that they pass through the inter-layer dielectric film 7 and the protective dielectric film 6 and contact the diffusion layers 1A and 1B.

As described above, the Resistor is broadly constituted by arranging the gate dielectric film 3 and the gate electrode 21 three-dimensionally inside the trench 1a, and by arranging the contact plugs 4 and 5 on the diffusion layers 1A and 1B respectively. Characteristic features of this embodiment are that the protective dielectric film 6, which has a different intended function from that of the inter-layer dielectric film 7, is formed over the top faces of the diffusion layers 1A and 1B, and that the metal gate electrode extension part 22, which has a width that is equivalent to the width (L6) of the trench 1a (i.e. a width {L2} that is greater than the width of the gate electrode 21 by an amount equal to the thickness of the gate dielectric film 3), is formed over the trench 1a that passes through the protective dielectric film 6.

According to the structure of the semiconductor device H shown in FIG. 2, since the diffusion layers 1A and 1B are covered by the protective dielectric film 6, this can suppress scattering of metal material into them (metal contamination) during processing of the metal gate electrode extension part 22 in the manufacturing method described later. Therefore, a sidewall dielectric film for preventing metal contamination, which is required in the conventional art, need not be provided around the gate electrode extension part 22. Since this enables the width of the gate electrode extension part 22 to be increased, increase in gate resistance can be suppressed even if the gate electrode is further miniaturized by making the width of the trench 1a narrower than in the conventional art.

If the structure of the semiconductor device 14 shown in FIGS. 2A to 2C is used, even a miniaturized gate structure can be manufactured more easily than in the conventional art. This point will be explained in detail together with the manufacturing method, while referring to the series of manufacturing steps shown in FIG. 2A to 5C.

### Method of Manufacturing Recessed Semiconductor Device (Recessed Transistor)

Firstly, as shown in FIGS. 3A to 3C, the active regions 11 are formed in partition by forming the element separating dielectric film 12 on the semiconductor substrate 1 using a known method such as shallow trench isolation (STI). A pad silicon oxide film 6a having a thickness of 10 nm is formed over the surface of the active region 11 using thermal oxidation. After implanting boron ions with an energy level of 300 keV at a dosage of 1×10¹³/cm², boron ions with a level of 100 keV are implanted at 4×10¹²/cm², forming a P-well (not shown). A protective dielectric film 6 of nitride silicon having a thickness of 120 nm is then formed over the entire surface using CVD.

A gate electrode inversion resist pattern is patterned on the protective dielectric film 6 using photolithography, and this pattern is used as a mask in performing dry etching of the protective dielectric film 6 and the pad silicon oxide film 6a, thereby exposing the surface of the active region 11 and the element separating dielectric film 12. After removing the resist used as the mask, the silicon of the active region 11 is etched to a depth of, for example, 150 nm using the protective dielectric film 6 as a mask. As shown in FIG. 3A, this results in the formation of a trench 1a having a trench width L6. In this embodiment, the trench width L6 is processed to 90 nm. Fluorine-containing plasma can be used to etch the protective dielectric film 6. Plasma containing a mixed gas of chlorine and oxygen can be used to etch the silicon. In his silicon etching, the element separating dielectric film 12 is also etched to approximately 30 nm.

Although the target of the etching step is the silicon of the active region, and the element separating dielectric film 12 itself need not be etched, since it is difficult to etch only the silicon of the active region, the element separating dielectric film 12 is also slightly etched.

It is technically difficult to etch the silicon of the active region at the same rate as the silicon oxide of the element separating region. La simultaneous etching of silicon and silicon oxide, the silicon is preferably etched at least five times more speedily. Therefore, while it is possible to use silicon oxide for the protective dielectric film 6, it is most preferable to use nitride silicon for the protective dielectric film 6 in order to facilitate associated processes such as its use as a stopper during a CMP step explained later.

FIG. 3B is a cross-sectional view along Y1-Y2 during this stage. Since the silicon of the active region 11 is etched to 150 nm, and the element separating dielectric film 12 is etched to 30 nm, a step of 120 nm is created at the interface between the active region 11 and the element separating dielectric film 12. After performing silicon etching, boron channel ions of 15 keV are implanted at a dosage of 1×10¹³/cm².

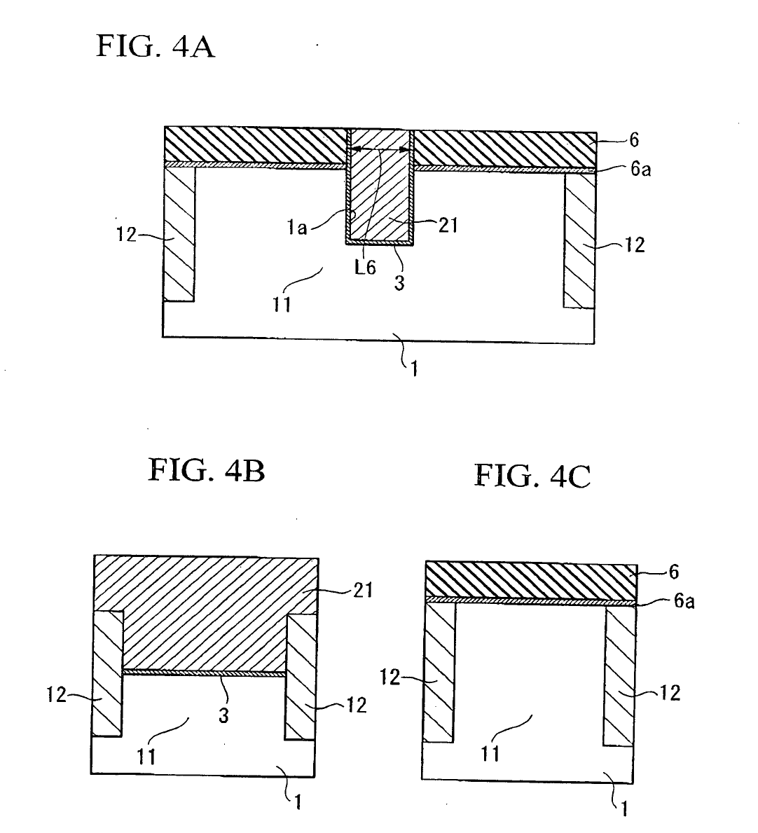

Subsequently, as shown in FIGS. 4A to 4C, after performing a surface cleaning process, a gate dielectric film 3 of silicon oxide having a thickness of 6 nm is formed by thermal oxidation on the inner faces of the trench 1a. A phosphorous-doped silicon film having a thickness of 70 nm is then formed over the entire face using CVD using silane (SiH₄) and phosphine (PH₃) as raw gases. The gate dielectric film 3 can be formed by a combination of CVD and thermal oxidation. In that case, for example, thermal oxidation to a thickness of 6 nm is additionally performed after forming a silicon oxide film of 5 nm by CVD.

In this embodiment, the trench width L6 is 90 nm, and the internal part of the trench 1a is completely filled with silicon film by forming a silicon film of 70 mm. The silicon film can be formed in a conductive polycrystalline state, or formed in an amorphous state and subsequently made conductive by processing it thermally to a polycrystalline state.

The silicon film on the protective dielectric film 6 is then removed by chemical mechanical polishing (CMP) using the protective dielectric film 6 as a stopper, whereby the gate dielectric film 3 and the gate electrode 21 of polysilicon film are formed in the trench 1a. During this stage, the top face of the protective dielectric film 6, the top part of the gate dielectric film 3, and the top face of the gate electrode 21 are all arranged in a single plane.

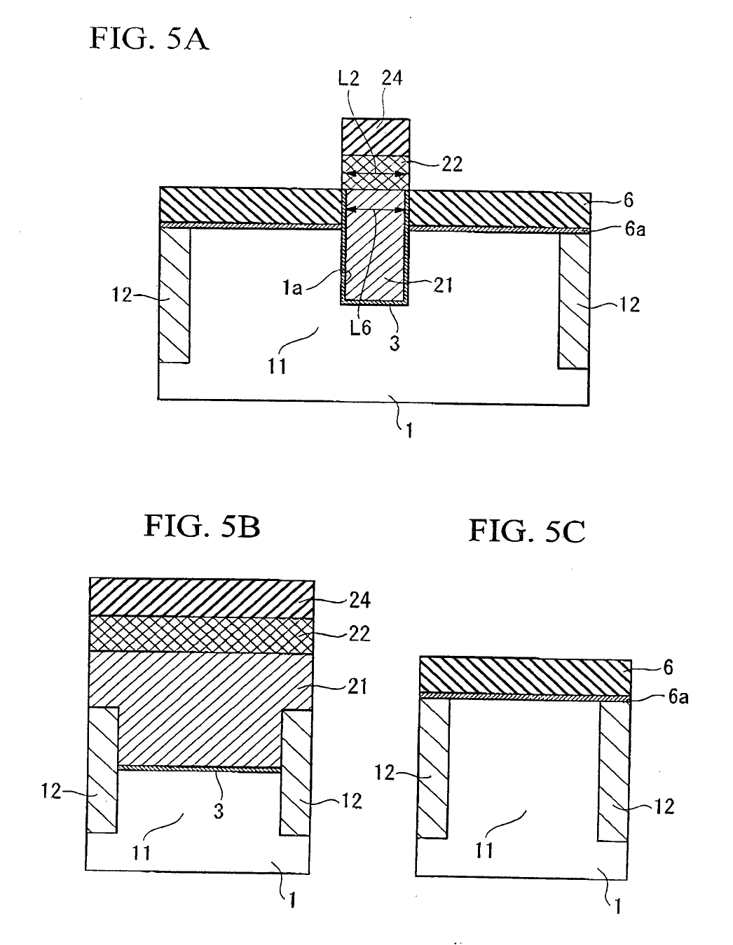

Subsequently, as shown in FIGS. 5A to 5C, after deposition of a metal film containing tungsten and a mask dielectric film for metal film processing comprising a silicon nitride film, the mask dielectric film and the metal film are sequentially transferred and etched by photolithography and dry etching. Fluorine-containing plasma can be used in etching the mask dielectric film, and chlorine-containing plasma can be used in etching the metal film.

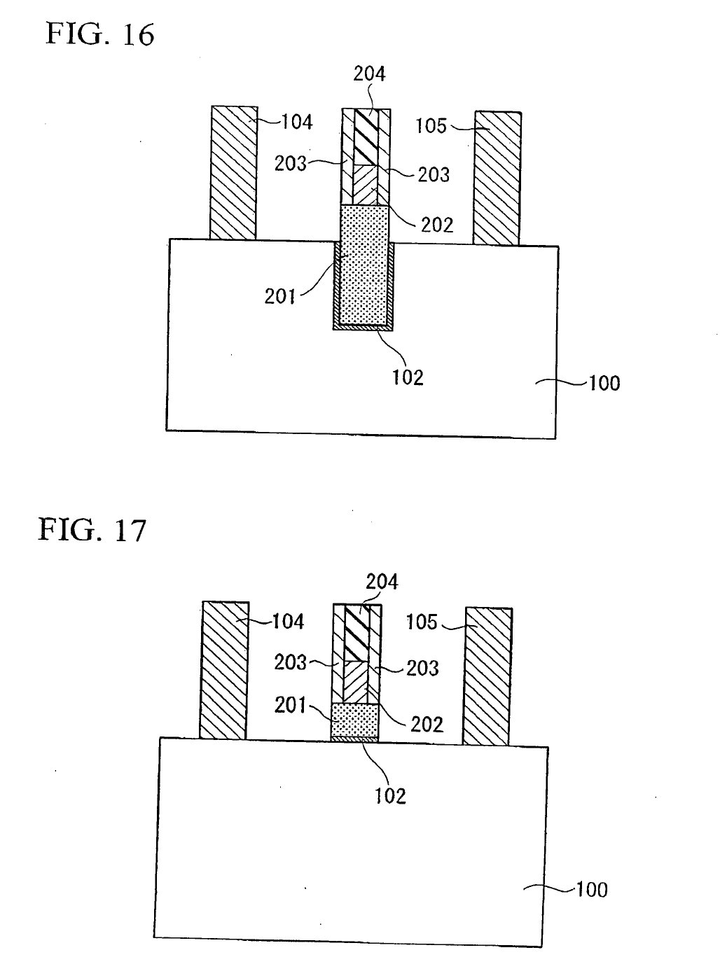

In this stage, a laminated structure including the gate electrode extension part 22 and the mask dielectric film 24 is formed over the gate electrode 21. Since the surface of the active region 11 becoming the diffusion layers 1A and 1B is covered by the protective dielectric film 6 at this time, even if the side faces of the metal film are exposed and metal atoms become detached, these atoms can be prevented from being scattered into the active region 11. Therefore, there is no need for the protective dielectric film (side wall dielectric film) 203 for preventing metal contamination (see FIGS. 12, 14, 16, and 17) that was required in the conventional art. This enables the width L2 to be made equal or greater than the width L6, whereby, when the gate is further miniaturized, processing is easier than in the structure of the conventional art; in addition, increase in gate resistance can be suppressed.

Subsequently, as shown in FIGS. 2A to 2C, an inter-layer dielectric film 7 is formed such as to embed the mask dielectric film 24, and, after its surface has been flattened by CMP, photolithography and dry etching are performed to make contact holes passing through the inter-layer dielectric film 7, the protective dielectric film 6, and the pad silicon oxide film 6a. Impurities are introduced into the active region 11 by ion implantation, creating regions for the diffusion layers 1A and 1B that will become a source and a drain. Here, after implanting arsenic with an energy level of 10 keV at a dosage of 4×10¹³/cm², phosphorous of 30 KeV is implanted at 5×10¹²/cm². Using a known method, the contact holes are embedded with a conductive material to form contact plugs 4 and 5. Incidentally, ion implantation can be performed after forming the pad silicon oxide film 6a, or after forming the gate electrode 21 and the like.

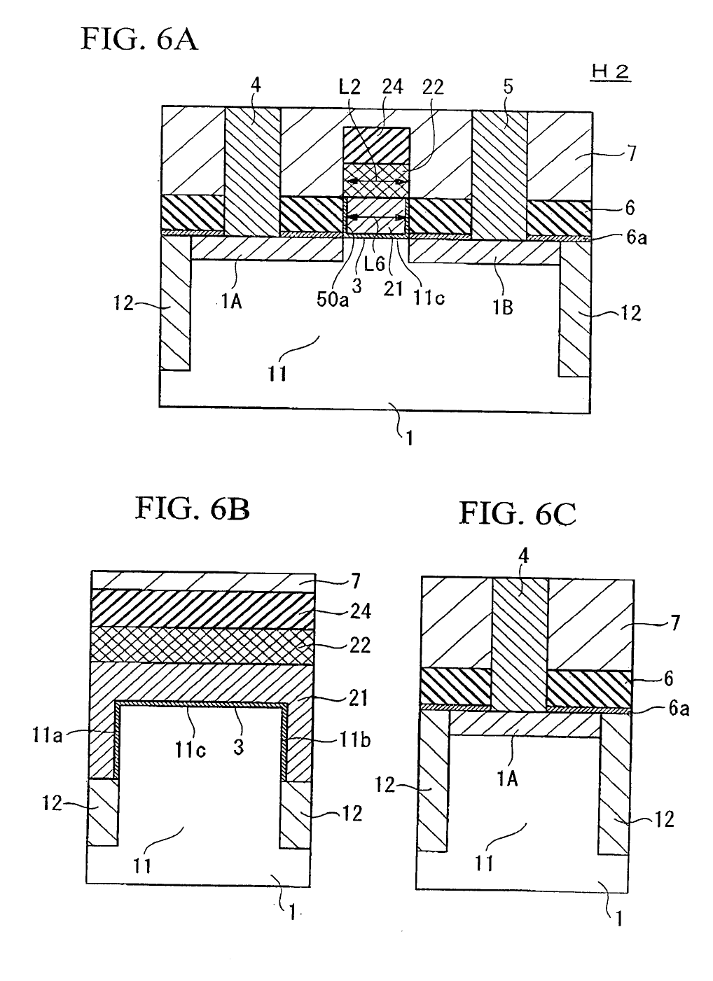

FIGS. 6A to 6C are diagrams of a second embodiment of the present invention, being conceptual views of a cross-sectional structure of a semiconductor device having a Fin-field effect transistor (Fin-FET) structure. The conceptual view of the planar structure is the same as that of the first embodiment shown in FIG. 1.

As shown in FIG. 6A, in a semiconductor device (Fin-FET) H2 of this embodiment, a protective dielectric film 6 is formed on the surface of a semiconductor substrate 1 with a pad silicon oxide film 6a therebetween. A trench 50a is formed through the protective dielectric film 6 and the pad silicon oxide film 6a such as to expose a top face 11c of an active region 11. A gate dielectric film 3 is formed over inner face sides of the trench 50a. A gate electrode 21 made from a conductive material such as polysilicon is formed on the inner side of the gate dielectric film 3. The trench 50a passes through the protective dielectric film 6 and the pad silicon oxide film 6a, and reaches the top face 11c of the active region 11, which is formed in an unengraved state. Therefore, as shown in FIG. 6A, the gate dielectric film 3 is U-shaped in cross-section, with its left and right side walls contacting the protective dielectric film 6, its top side arranged in a single plane with the top face of the protective dielectric film 6 and the top face of the gate electrode 21, and its bottom side contacting the top face 11c of the active region 11.

A gate electrode extension part 22 made from a conductive metal material such as tungsten is provided on the gate electrode 21 such as to upwardly extend the gate electrode 21. The width of the gate electrode extension part 22 is equal to the width of the gate electrode 21 plus the thicknesses of the gate dielectric film 3 on both sides of the gate electrode 21. A mask dielectric film 24 is provided on the gate electrode extension part 22.

Diffusion layers 1A and 1B are then formed on the surface of the active regions 11 such as to sandwich the part including the trench 50a between them, the diffusion layer 1A that will be the source being provided on one side of that part and the diffusion layer 1B that will be the drain being provided on the other side. An inter-layer dielectric film 7 is provided on the protective dielectric film 6, and contact plugs 4 and 5 are formed such that they pass through the inter-layer dielectric film 7, the protective dielectric film 6, and the pad silicon oxide film 6a, and respectively contact the diffusion layers 1A and 1B.

In the cross-sectional view along Y1-Y2 shown in FIG. 6B, an element separating dielectric film is dug adjacent to the active region 11. The active region 11 has a fin structure constituted by side faces 11a and 11b and a top face 11c. The gate dielectric film 3 is formed on these three faces of the active region 11 (the side faces 11a and 11b, and the top face 11c), and the gate electrode 21 is provided such as to cover the gate dielectric film 3. The gate electrode extension part 22, the mask dielectric film 24, and the inter-layer dielectric film 7 are laminated over the gate electrode 21.

In the cross-sectional view along Y3-Y4 shown in FIG. 6C, as in the first embodiment, the diffusion layer 1A is formed on the surface of the active region 11 sandwiched by the element separating dielectric film 12, and the contact plug 4 is formed such that it passes through the pad silicon oxide film 6a, the protective dielectric film 6, and the inter-layer dielectric film 7, and contacts the diffusion layer 1A.

Thus in the structure shown in FIGS. 6A to 6C, a Fin-FET structure is broadly constituted by: the gate dielectric film 3 arranged three-dimensionally on the inner face sides of the trench 50a so as to correspond to the fin structure of the active region 11; and the contact between the contact plugs 4 and 6 and the diffusion layers 1A and 1B. Characteristic features of this embodiment are that the protective dielectric film 6 is provided on the top face side of the active region 11, and that the gate electrode extension part 22 which has the same width as the width (L6) of the trench 50a (in other words, a width {L2} that is larger than the width of the gate electrode 21 by an amount equivalent to the thickness of the gate dielectric film 3) is formed above the trench 50a that passes through the protective dielectric film 6.

In the structure of the semiconductor device H2 shown in FIGS. 6A to 6C, since the surfaces of the diffusion layers 1A and 1B of the active region 11 are covered by the protective dielectric film 6, when forming the metal gate electrode extension part 22 in a manufacturing method described later, scattering and infiltration of metal to the diffusion layers 1A and 1B of the active region 11 (metal contamination) can be suppressed. Therefore, there is no need for a sidewall dielectric film for preventing metal contamination that encloses a gate electrode extension part in the conventional art. Since this enables the width of the gate electrode extension part 22 to be increased, the trench 50a can be made narrower than in the conventional art, facilitating miniaturization of the gate and suppressing increase in the gate capacity.

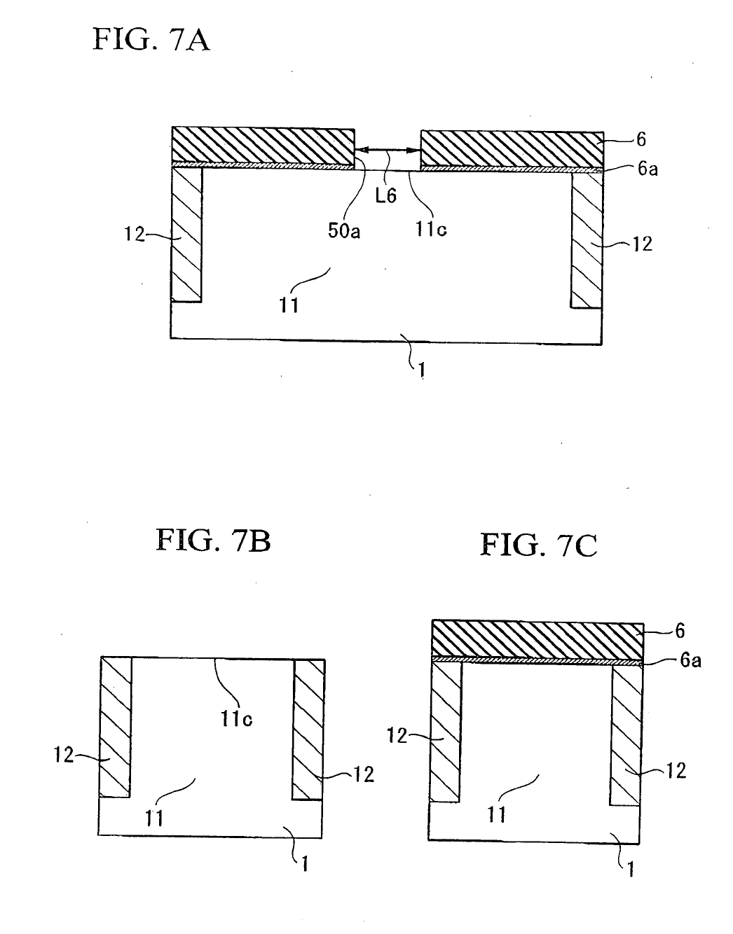

By using the structure of the semiconductor device H2 shown in FIGS. 6A to 6C, even this miniaturized gate structure can be manufactured more easily than the structure of the conventional art. This point will be explained in detail below during an explanation of a manufacturing method using FIGS. 7A to 10C.

### Method of Manufacturing Fin-Field Effect Transistor (Fin-FET)

Firstly, as shown in FIGS. 7A to 7C, an element separating dielectric film 12 is formed on a semiconductor substrate 1 using a known STI method, and the active regions 11 are formed in partition. A pad silicon oxide film 6a having a thickness of 10 nm is then formed over the surfaces of the active regions 11 using thermal oxidation. After implanting boron ions with an energy level of 300 keV at a dosage of 1×10¹³/cm², boron ions with a level of 100 keV are implanted at 4×10¹²/cm², forming a P-well (not shown). A protective dielectric film 6 of nitride silicon having a thickness of 130 nm is then formed over the entire surface using CVD.

A gate electrode inversion resist pattern is patterned on the protective dielectric film 6 using photolithography, and this pattern is used as a mask in performing dry etching of the protective dielectric film 6 and the pad silicon oxide film 6a, thereby forming a trench 50a having a width L6. This exposes a top face 11c of the active region 11 along the cross-section X1-X2 shown in FIG. 7A. In the cross-section Y1-Y2 shown in FIG. 7B, the top face 11c of the active region 11 and a surface of the element separating dielectric film 12 adjacent thereto are exposed. In the cross-section Y3-Y4 shown in FIG. 7C, the top face 11c of the active region 11 and a surface of the element separating dielectric film 12 adjacent hereto are covered with the protective dielectric film 6.

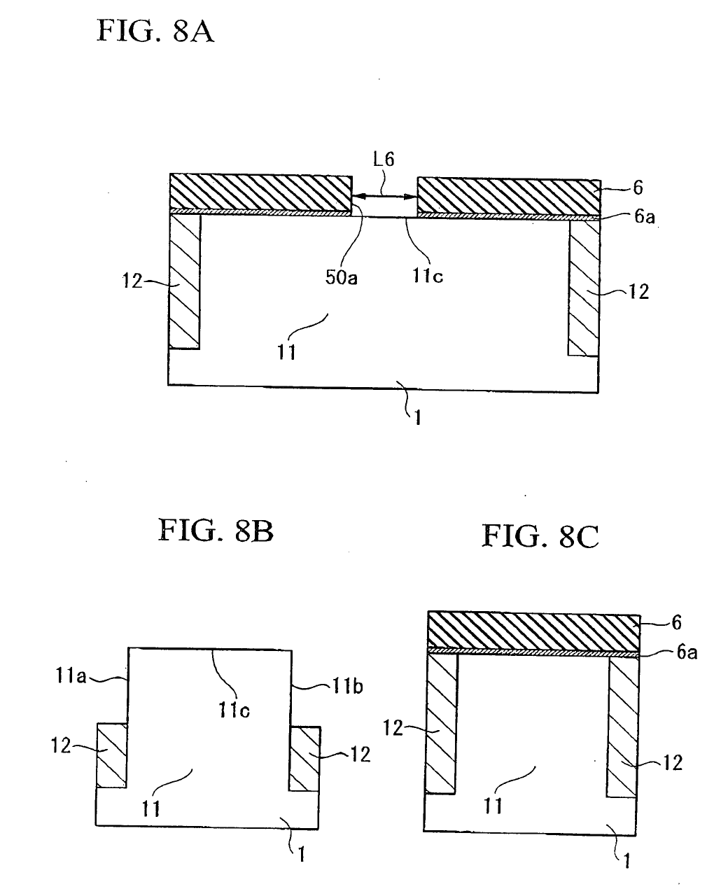

As shown in FIG. 8B, the exposed surface of the element separating dielectric film 12 is etched to 80 nm, exposing the side faces 11a and 11b of the active region 11 and forming a fin structure constituted by the side faces 11a and 11b and the top face 11c. This etching can be performed using a gas formed by mixing octafluorocyclobutane (C₄F₈), argon (Ar), and oxygen (O₂) at a rate of, for example, 10, 500, and 5 standard cubic centimeters per minute (sccm), respectively, and performing plasma etching at a pressure of 50 m Torr and at a high-frequency power of 800 W. At this time, the top face 11c of the silicon active region 11 is hardly etched at all (etching amount=4 nm). On the other hand, the nitride silicon protective dielectric film 6 is etched to 30 nm, leaving a film thickness of 100 nm. A gas such as octafluorocyclopentane (C₅F₆) and hexafluorocyclobutane (C₄F₆) can be used instead of octafluorocyclobutane. No structural changes occur in the cross-sections of FIGS. 8A and 8C. While the side faces 11a and 11b and the top face 11c of the active region 11 are exposed, channel ions are implanted by vertical or tilted implantation.

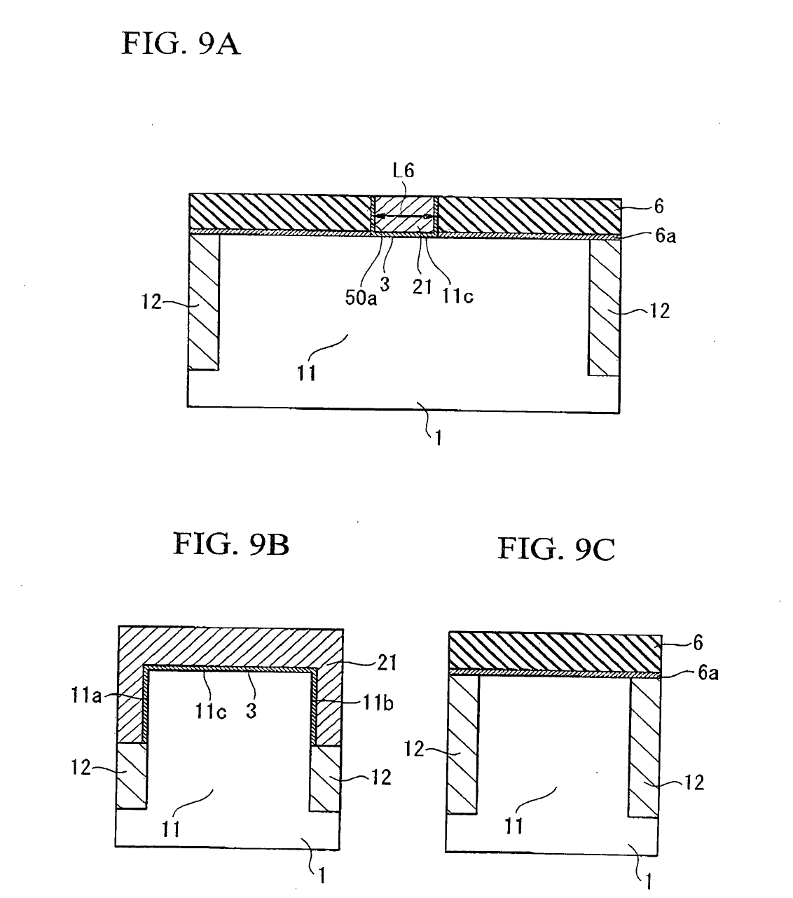

As shown in FIGS. 9A to 9C, a gate dielectric film 3 of silicon oxide having a thickness of 6 nm is formed by thermal oxidation over the exposed surfaces 11a and 11b and the top face 11 of the active region 11. A phosphorous-doped silicon film having a thickness of 70 nm is formed by CVD over the entire faces. The trench 50a has a width L6 of 90 nm, and is completely filled with a silicon film by deposition of 70 nm.

The silicon film on the protective dielectric film 6 is removed by chemical mechanical polishing (CMP) using the protective dielectric film 6 as a stopper, whereby the gate dielectric film 3 and the gate electrode 21 of polysilicon film are formed in the trench 50a. During this stage, the top face of the protective dielectric film 6, the top part of the gate dielectric film 3, and the top face of the gate electrode 21 are all arranged in a single plane.

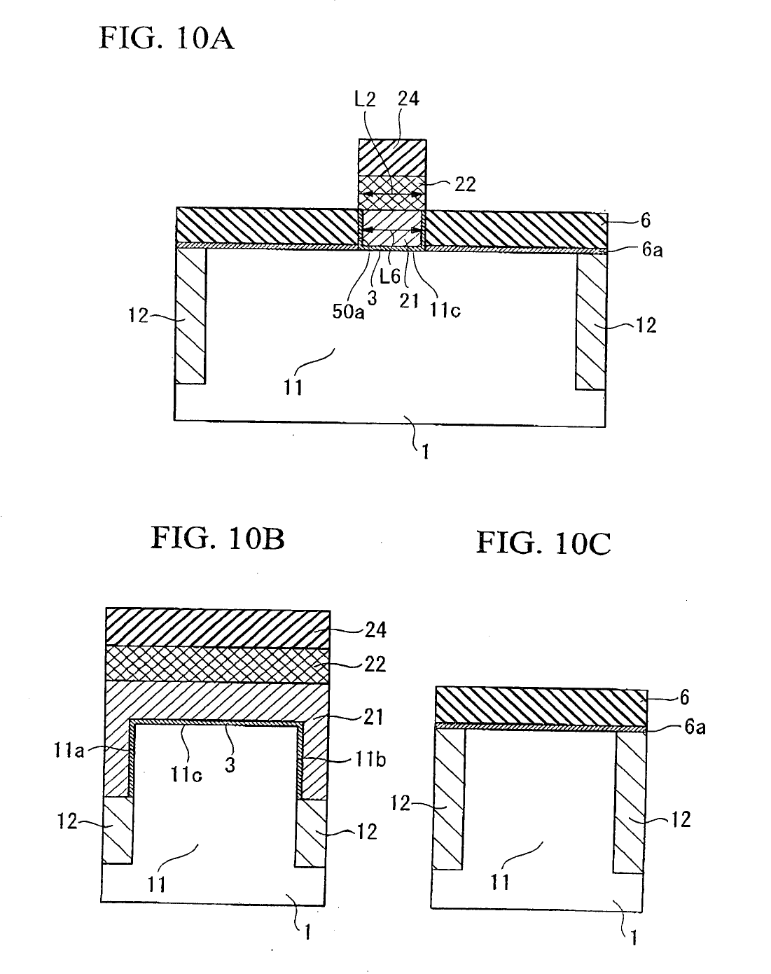

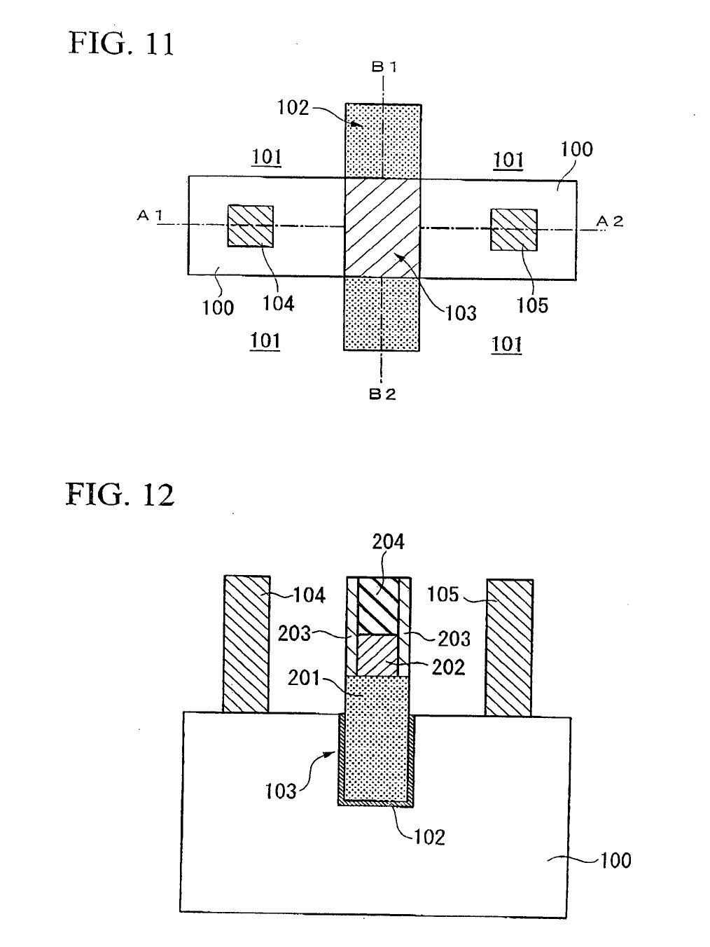

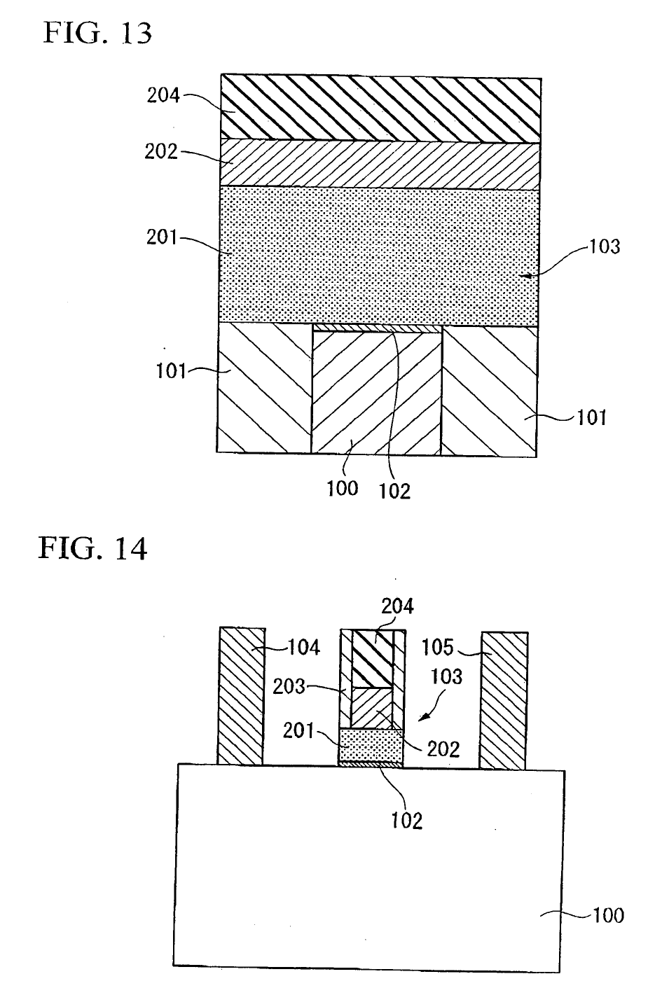

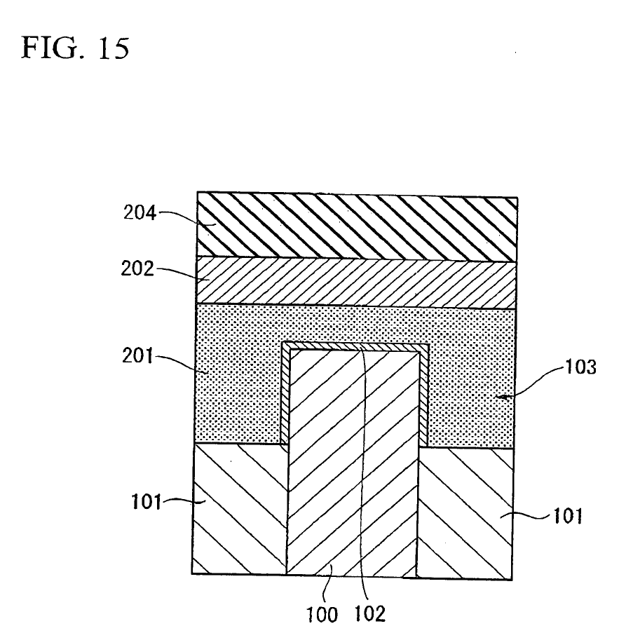

Subsequently, as shown in FIGS. 10A to 10C, after deposition of a metal film containing tungsten and a mask dielectric film for metal film processing comprising a silicon nitride film, the mask dielectric film and the metal film are sequentially transferred and etched by photolithography and dry etching. Fluorine-containing plasma can be used in etching the mask dielectric film, and chlorine-containing plasma can be used in etching the metal film.

In this stage, a laminated structure including the gate electrode extension part 22 and the mask dielectric film 24 is formed over the gate electrode 21. Since the surface of the active region 11 becoming the diffusion layers 1A and 1B is covered by the protective dielectric film 6 at this time, even if the side faces of the metal film are exposed and metal atoms become detached, these atoms can be prevented from being scattered into the active region 1.

Therefore, there is no need for the protective dielectric film (side wall dielectric film) 203 for preventing metal contamination (see FIGS. 12, 14, 16, and 17) that was required in the conventional art. This enables width L2 to be made equal or greater than width L6, whereby, when the gate is further miniaturized, processing is easier than in the structure of the conventional art; in addition, increase in gate resistance can be suppressed.

Subsequently, as shown in FIGS. 6A to 6C, an inter-layer dielectric film 7 is formed such as to embed the mask dielectric film 24, and, after its surface has been flattened by CMP, photolithography and dry etching are performed to make contact holes passing through the inter-layer dielectric film 7, the protective dielectric film 6, and the pad silicon oxide film 6a. Impurities are then introduced into the active region 11 by ion implantation, creating regions for the diffusion layers 1A and 1B that will become a source and a drain. Here, after implanting arsenic with an energy level of 10 keV at a dosage of 4×10¹³/cm², phosphorous of 30 keV is implanted at 5×10¹²/cm². Using a known method, the contact holes are embedded with a conductive material to form contact plugs 4 and 5. Incidentally, ion implantation can be performed after forming the gate electrode 21 and the like.

While preferred embodiments of the present invention have been described and illustrated above, it should be understood that these are exemplary of the present invention and are not to be considered as limiting. Additions, omissions, substitutions, and other modifications can be made without departing from the gist or scope of the present invention. Accordingly, the present invention is not to be considered as being limited by the foregoing description, and is only limited by the scope of the appended claims.

What is claimed is:

1. A semiconductor device comprising:
a three-dimensional gate dielectric film formed on a semiconductor substrate;
a gate electrode that contacts the gate dielectric film and protrudes from the semiconductor substrate;
a source electrode and a drain electrode that are formed in a diffusion layer region of the semiconductor substrate around the gate dielectric film;
a protective dielectric film that covers a top face of the semiconductor substrate around the gate electrode and a side face of the gate electrode protruding from the semiconductor substrate; and
an inter-layer dielectric film that is laminated over the protective dielectric film.

2. The semiconductor device as recited in claim 1, wherein a top face of the protective dielectric film, a top face of the gate dielectric film, and a top face of the gate electrode are polished by chemical mechanical polishing so as to be aligned in a single plane.

3. The semiconductor device as recited in claim 1, further comprising a gate electrode extension part whose side face is exposed and t is formed on the gate electrode, wherein the gate electrode is surrounded by the protective dielectric film, and the gate electrode extension part is positioned above the protective dielectric film.

4. The semiconductor device as recited in claim 1, wherein the diffusion layer region becomes a source region and a drain region, the source electrode passes through the protective dielectric layer and contacts the source region, and the drain electrode passes through the protective dielectric film and contacts the drain region.

5. The semiconductor device as recited in claim 1, further comprising a gate electrode extension part that is laminated on the gate electrode, wherein the thickness of the gate electrode extension part is equal to or greater than the width of a trench in which the gate electrode and the gate dielectric film are formed.

6. The semiconductor device as recited in claim 1, further comprising a conductive part that is laminated on the gate electrode, wherein the width of the conductive part is equal to or greater than the width of a trench in which the gate dielectric film and the gate electrode are formed, and a side face of the conductive part is exposed.

7. A semiconductor device comprising:
a recessed channel transistor including a trench formed in a semiconductor substrate; a gate electrode formed in the trench with a gate dielectric film therebetween, at least a part of the gate electrode extending above the semiconductor substrate; a diffusion layer region arranged in the semiconductor substrate near the gate electrode with the gate dielectric film therebetween; and a source electrode and a drain electrode that contact the diffusion layer region;
a gate electrode extension part that is made of a conductive material and is laminated on the gate electrode so as to extend the gate electrode;
a protective dielectric film that covers the semiconductor substrate around the gate electrode and surrounds a side face of the gate electrode that protrude from the trench; and
an inter-layer dielectric film formed over the protective dielectric film.

8. The semiconductor device as recited in claim 7, wherein a top face of the protective dielectric film, a top face of the gate dielectric film, and a top face of the gate electrode are polished by chemical mechanical polishing so as to be aligned in a single plane.

9. The semiconductor device as recited in claim 7, wherein the gate electrode is surrounded by the protective dielectric film, and the gate electrode extension part is positioned above the protective dielectric film.

10. The semiconductor device as recited in claim 7, wherein the diffusion layer region becomes a source region and a drain region, the source electrode passes through the protective dielectric layer and contacts the source region, and the drain electrode passes through the protective dielectric film and contacts the drain region.

11. The semiconductor device as recited in claim 7, wherein the thickness of the gate electrode extension part is equal to or greater than the width of the trench in which the gate electrode and the gate dielectric film are formed.

12. The semiconductor device as recited in claim 7, wherein the gate electrode extension part is a conductive part having a width that is equal to or greater than the width of the trench in which the gate dielectric film and the gate electrode are formed, and a side face of the conductive part is exposed.

13. A semiconductor device comprising:
a transistor including a protective dielectric film formed on a semiconductor substrate; a trench formed in the protective dielectric film so as to reach the semiconductor substrate; a gate electrode formed in the trench with a gate dielectric film therebetween; a diffusion layer region arranged in the semiconductor substrate near the gate electrode with the gate dielectric film therebetween; and a source electrode and a drain electrode that contact the diffusion layer region;
a gate electrode extension part made of a conductive material and laminated on the gate electrode so as to extend the gate electrode;
a protective dielectric film that covers the semiconductor substrate around the gate electrode and surrounds a side face of the gate electrode; and
an inter-layer dielectric film formed over the protective dielectric film.

14. The semiconductor device as recited in claim 13, wherein a top face of the protective dielectric film, a top face of the gate dielectric film, and a top face of the gate electrode are polished by chemical mechanical polishing so as to be aligned in a single plane.

15. The semiconductor device as recited in claim 13, wherein the gate electrode is surrounded by the protective dielectric film, and the gate electrode extension part is positioned above the protective dielectric film.

16. The semiconductor device as recited in claim 13, wherein the diffusion layer region becomes a source region and a drain region the source electrode passes through the protective dielectric layer and contacts the source region, and the drain electrode passes through the protective dielectric film and contacts the drain region.

17. The semiconductor device as recited in claim 13, wherein the thickness of the gate electrode extension part is equal to or greater than the width of the trench in which the gate electrode and the gate dielectric film are formed.

18. The semiconductor device as recited in claim 13, wherein the gate electrode extension part is a conductive part having a width that is equal to or greater than the width of the trench in which the gate dielectric film and the gate electrode are formed, and a side face of the conductive part is exposed.

19. A method of manufacturing a semiconductor device comprising:
forming an element separating dielectric film in a semiconductor substrate where a diffusion layer region is formed;
forming a protective dielectric film on the semiconductor substrate where the element separating dielectric film is formed;
patterning the protective dielectric film, and forming a trench by etching the protective dielectric film and the semiconductor substrate while using the patterned protective dielectric film as a mask;
forming a gate dielectric film along an inner face of the trench by performing an oxidation process to the diffusion layer region;
forming a gate electrode on an inner side of the gate dielectric film by forming a polysilicon layer on the semiconductor substrate;
flattening a surface of the semiconductor substrate by chemical mechanical polishing using the protective dielectric film as a stopper to align a top face of the protective dielectric film, a top face of the gate dielectric film, and a top face of the gate electrode in a single plane;
forming a gate electrode extension part comprising a conductive material on the gate electrode; and
forming a source electrode and a drain electrode that pass through the protective dielectric film and contact the diffusion layer region on a side of the gate dielectric film.

20. The method of manufacturing a semiconductor device as recited in claim 19, wherein when the gate electrode extension part is formed on the gate electrode, the gate electrode extension part is formed on the gate electrode in a state where the protective dielectric film covers a top face of the semiconductor substrate and prevents scattering of the conductive material.

21. The method of manufacturing a semiconductor device as recited in claim 19, wherein the gate electrode extension part is formed on the gate electrode such that a side part of the gate electrode extension part is exposed, and the width of the gate electrode extension part is equal to or exceeds the width of the gate electrode.

22. A method of manufacturing a semiconductor device comprising:
forming an element separating dielectric film a semiconductor substrate where a diffusion layer region is formed;
forming a protective dielectric film on the semiconductor substrate where the element separating dielectric film is formed;
patterning the protective dielectric film and forming a trench that reaches a surface of the semiconductor substrate;
forming, inside the trench, a gate dielectric film that reaches the semiconductor substrate and covers an inner face of the trench;
forming a gate electrode on an inner side of the gate dielectric film by forming a polysilicon layer on the semiconductor substrate;
flattening the surface of the semiconductor substrate by chemical mechanical polishing using the protective dielectric film as a stopper to align a top face of the protective dielectric film, a top face of the gate dielectric film, and a top face of the gate electrode in a single plane;
forming a gate electrode extension part comprising a conductive material on the gate electrode; and
forming a source electrode and a drain electrode that pass through the protective dielectric film and contact the diffusion layer region on a side of the gate dielectric film.

23. The method of manufacturing a semiconductor device as recited in claim 22, wherein when the gate electrode extension part is formed on the gate electrode, the gate electrode extension part is formed on the gate electrode in a state where the protective dielectric film covers a top face of the semiconductor substrate and prevents scattering of the conductive material.

24. The method of manufacturing a semiconductor device as recited in claim 22, wherein the gate electrode extension part is formed on the gate electrode such that a side part of the gate electrode extension part is exposed, and the width of the gate electrode extension part is equal to or exceeds the width of the gate electrode.
